(19) United States
(12) Patent Application Publication
(10) Pub. No.: US 2005/0085044 A1
(43) Pub. Date: Apr. 21, 2005

(54) Method for the production of a hetero-bipolar transistor

(76) Inventor: Axel Hulsmann, Freiburg (DE)

Correspondence Address: MERCHANT & GOULD PC, P.O. BOX 2903, MINNEAPOLIS, MN, 55402-0903, US

(21) Appl. No.: 10/502,441

(22) PCT Filed: Jan. 24, 2003
(86) PCT No.: PCT/DE03/00255

(30) Foreign Application Priority Data
Jan. 25, 2002 (DE) 102039666
Mar. 28, 2002 (DE) 102140731

(51) Int. Cl. H01L 21/331; H01L 21/8222

(52) U.S. Cl. 438/312; 438/319

(57) ABSTRACT

The invention relates to a method of manufacturing a heterobipolar transistor, wherein epitaxially grown layers (2 to 11) on a substrate (1) are structured by etching. An emitter contact (31) and a base contact (32) are formed by simultaneous metallizing of an emitter layer (11) and a base layer (6). This method reduces the number of method steps required to manufacture a heterobipolar transistor and thus cuts time and cost which must invested in production.

The invention relates to a method of manufacturing a heterobipolar transistor, wherein epitaxially grown layers on a substrate are structured by etching. It also relates to the use of the method for making a heterobipolar transistor.

Heterobipolar transistors (HBT) have a number of advantages in comparison with ordinary bipolar transistors. In particular, their very good frequency behavior has led to increasing usage of heterobipolar transistors in high frequency circuits such as needed, for instance, in mobile radio technology. Switching frequencies obtainable with heterobipolar transistors lie in a range above 100 GHz.

To manufacture heterobipolar transistors, first, semiconductor layers are grown epitaxially on a substrate. The structuring of these epitaxially grown layers essentially is performed in successive lithographic and etching steps. A lithographic step includes applying a photoresist, transferring a given pattern on a mask to the photoresist by exposure of the mask, and then developing the photoresist. In the subsequent etching step, only the semiconductor material not covered by photoresist is etched. Apart from the lithographic and etching steps, manufacturing comprises additional steps, such as metallizing semiconductor layers so as to form contacts.

It is already known to form individual structures of a heterobipolar transistor, such as an emitter, a base, collector, subcollector, emitter contact, base contact, collector contact, etc. in individual method steps. That requires a great number of lithographic masks. Each method step involves costs, either directly or indirectly by prolonging the necessary manufacturing time.

It is an object of the invention to provide a method of the kind specified initially, by which the number of method steps required is reduced, thus simplifying the method, especially eliminating at least one lithographic mask so that less time is needed for manufacturing a heterobipolar transistor which, in turn, is reflected by lower manufacturing costs.

This object is met, in accordance with the invention, by a method of manufacturing a heterobipolar transistor of the kind defined above, wherein an emitter contact and a base contact are formed by simultaneous metallizing of an emitter layer and a base layer.

It is an advantage or the invention that manufacturing of a heterobipolar transistor is expedited since one metallizing step is dispensed with, as compared to conventional manufacturing methods. Manufacturing costs consequently are lowered. Furthermore, one lithographic step is eliminated. A conventional manufacturing method for producing a heterobipolar transistor provides for the base layer to be fully covered with a photoresist film arrangement before the emitter contact is made. Thereafter the emitter contact is formed. The base layer cannot be metallized to form a base contact until a photoresist film arrangement has been provided in a lithographic step to determine the surface area extension of the base contact. With the method according to the invention, on the other hand, the first lithographic step mentioned is omitted. As it is very time consuming and expensive to make lithographic masks and carry out lithography, the production of a heterobipolar transistor thus is expedited additionally. At the same time, the cost of production is lowered still further. Moreover, with every lithographic step there is a risk of maladjusting the mask applied for lithography. When a lithographic mask is not optimally aligned with respect to the structures formed previously in other method steps this may result in a degradation of characteristics of the heterobipolar transistor or even bring about its inability to function at all. By doing with one lithographic step less, the method according to the invention, therefore, has less likelihood of producing a heterobipolar transistor which does not work or does not have the best possible characteristics.

In an advantageous further development of the invention, vaporization of platinum may be provided to effect the metallizing. Platinum, when directly plated an the base layer by vaporization, partly diffuses into the p⁺ doped base layer. The existing Schottky barrier level φ_{B} between the base layer and the metallic base contact is lowered as a result of the diffusion of the platinum atoms. Consequently, the resistance of the base contact is smaller than that of a known base contact.

In a convenient further development of the invention metallizing may be performed by vapor plating successive layers of metals, namely platinum, titanium, platinum, and gold. The vapor deposition of this sequence of metal layers creates a base contact which, on the one hand, has a low resistance value and, on the other hand, high stability and a high degree of corrosion resistance and very good electrical contact properties.

It may be provided in another advantageous further development to carry out etching of an emitter structure in consideration of crystal orientation and metal selection, prior to metallizing the emitter layer and the base layer, in such a way that etching edges of the emitter structure will have an undercut, the etching of the emitter structure being stopped in the zone of a spacer layer or the base layer. This has the advantage that, on the one hand, undercut etching edges of the emitter structure are obtained and, at the same time, the etching stops selectively, in consideration of the material, on the base layer. Selectivity of the material when etching permits to subject only the desired epitaxially grown semiconductor layers to the etching process. Undercutting the etching edges of the emitter structure has the advantage that the undercut edges cause partial shading of the base layer which is not etched as the emitter structure in vapor plated in vertical direction, and on which the etching stops. This shaded area of the base layer makes sure that there will be insulation between the base contact and the emitter structure.

In accordance with another advantageous embodiment of the invention, prior to etching the base layer, a photoresist film may be applied around the etched emitter structure so that the emitter structure will be fully enclosed by photoresist material and at least part of a surrounding portion of the base contact remote from the emitter structure will not be covered by photoresist. Applying the photoresist at such locations in a lithographic step is advantageous in that it offers a certain degree of freedom for aligning the mask with respect to the emitter structure already formed, in the lithographic step to apply the photoresist film. That part of the surrounding portion of the base contact not covered by photoresist defines the dimension of the base structure or the collector structure underneath it. The photoresist need not do anything but protect the emitter structure during the etching process by which the base layer is structured.

An advantageous further development of the method according to the invention may reside in fully etching under a metallic base lead which extends between the base contact and a base connection port, whereby an air bridge is formed. By devising the metallic base lead as an air bridge, the capacitance is reduced between the base lead and the collector/subcollector. Thus the switching properties of a heterobipolar resistor are improved.

According to another convenient further development of the invention a collector structure may be formed after structuring the base layer and between two successive lithographic steps. That is advantageous in that the costs for producing a heterobipolar transistor are reduced still further.

Furthermore, it may be advantageous to etch at least part of the collector structure in consideration of material selection so that etching edges of the collector structure will have an undercut and the etching will stop on a subcollector material. Selectivity of material, when etching, makes it possible to control and supervise the course of the etching fairly easily by process engineering. Undercutting the collector structure has the advantage of obtaining a collector structure which causes shading of part of the subcollector material when the collector contact is formed. In this manner, insulation between the collector structure and the collector contact is warranted automatically. This means that the collector contact is self-adjusted with respect to the collector structure.

According to a useful further development the epitaxially grown layers comprise III-V semiconductor materials. This embodiment profits from the fact that the technology of epitaxial growth of lattice adapted III-V semiconductor layers on a substrate is well advanced. Moreover, heterobipolar transistors made of III-V semiconductor materials are high performance, efficient heterobipolar transistors.

The invention will be described further, by way of example, with reference to a drawing, in which:

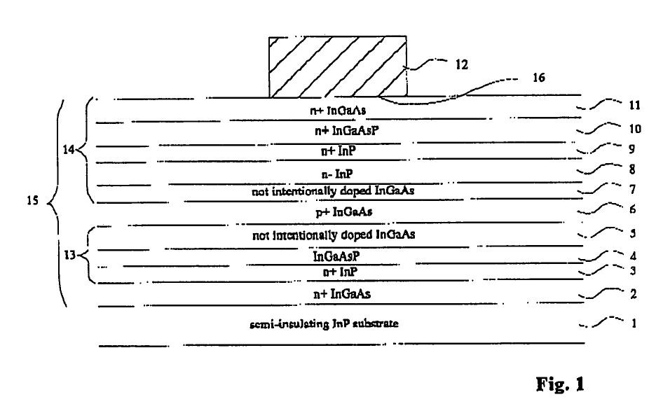

FIG. 1 shows part of a blank for making a heterobipolar transistor, comprising epitaxially grown semiconductor layers on a substrate;

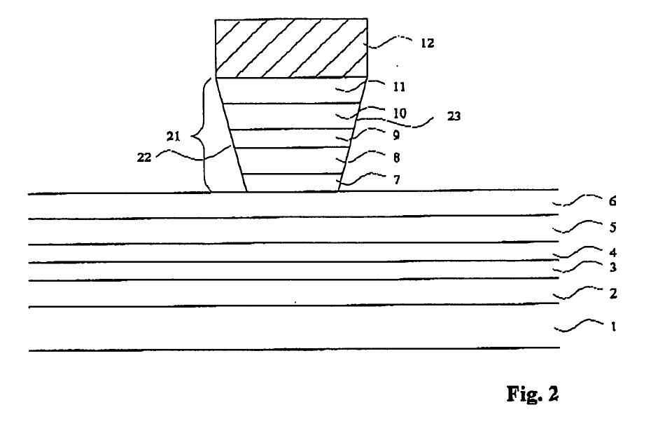

FIG. 2 shows the blank of FIG. 1 after emitter etching;

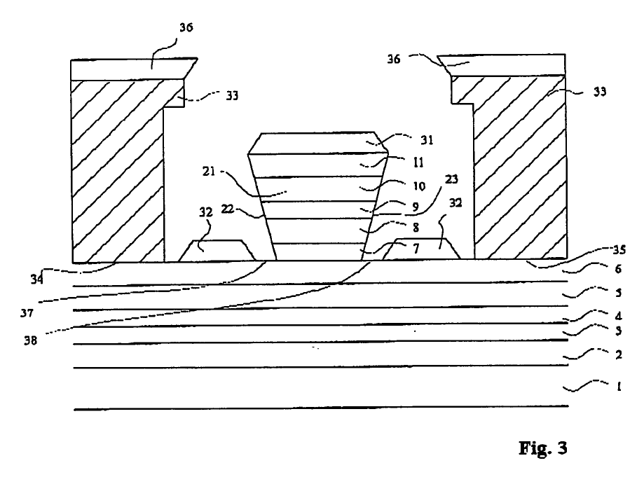

FIG. 3 shows the blank of FIG. 1 after metallizing of an emitter layer and a base layer;

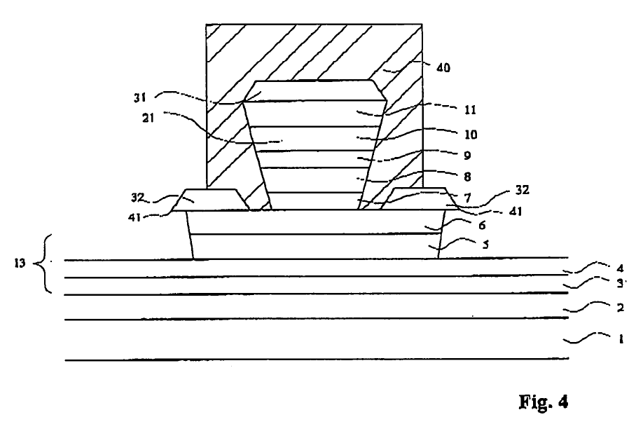

FIG. 4 shows the blank of FIG. 1 during structuring of a collector;

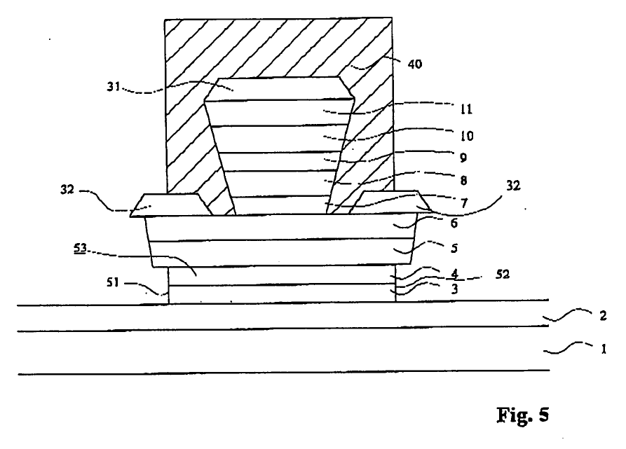

FIG. 5 shows the blank of FIG. 1 upon termination of the collector structuring;

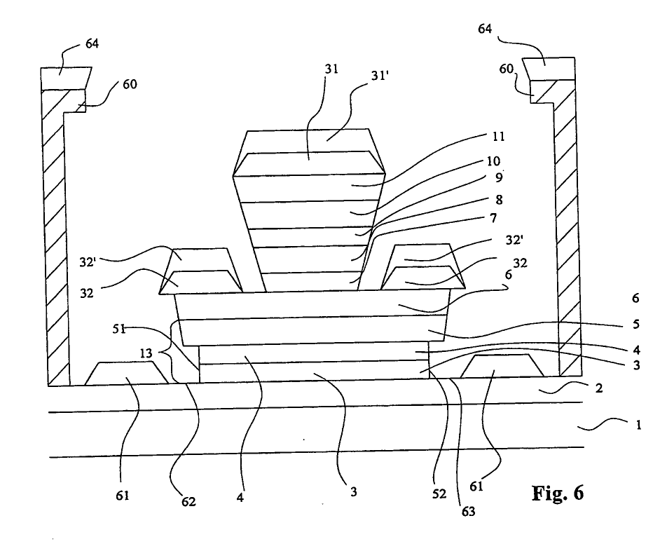

FIG. 6 shows the blank of FIG. 1 after the formation of collector contacts;

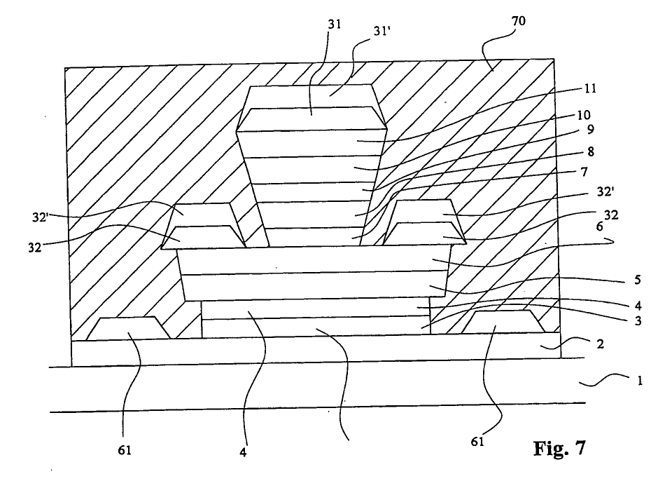

FIG. 7 shows the blank of FIG. 1 after etching of a subcollector for insulation of the heterobipolar transistor;

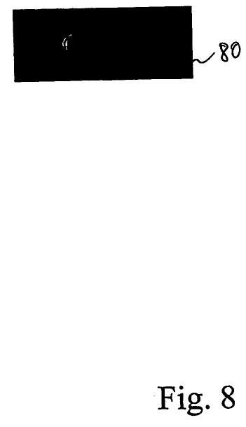

FIG. 8 is a diagrammatic presentation of a mask level for emitter structuring of the blank shown in FIG. 1;

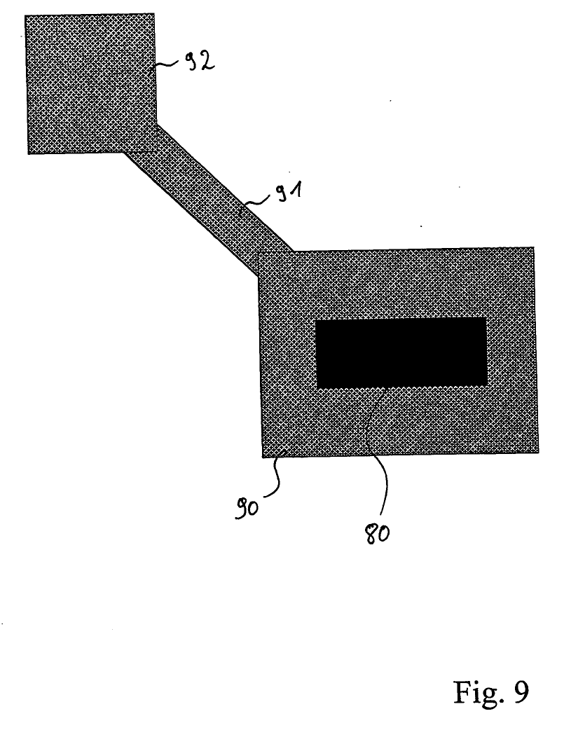

FIG. 9 is a diagrammatic presentation of a mask level for forming the emitter contact, base contact, and a base connection contact as well as a base lead;

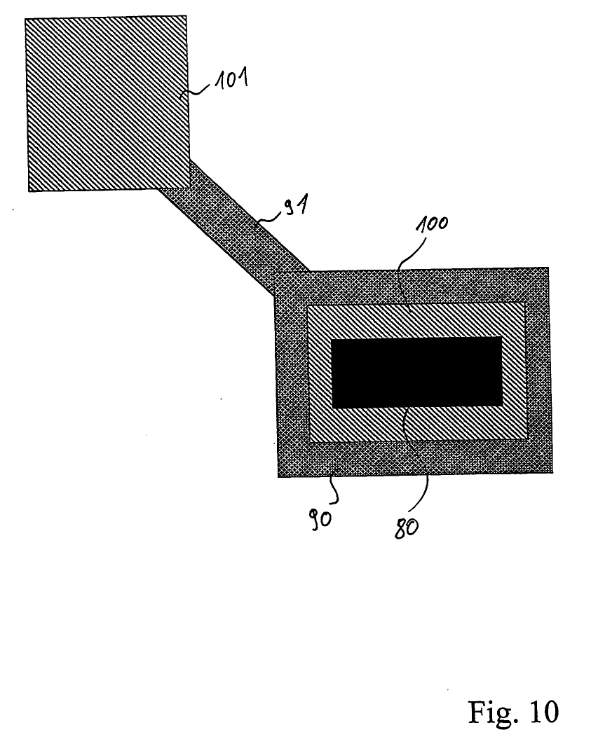

FIG. 10 is a diagrammatic presentation of a mask level for collector structuring;

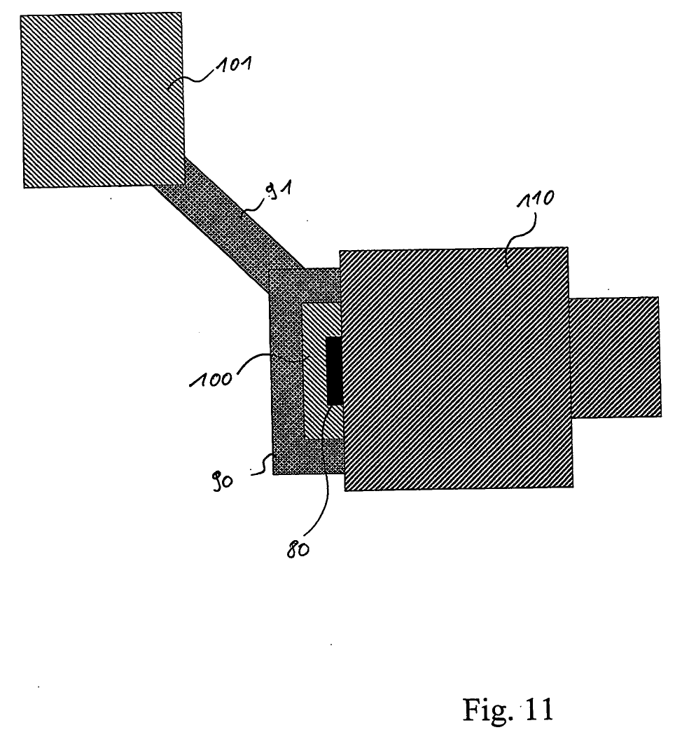

FIG. 11 is a diagrammatic presentation of a mask level for forming a collector contact; and

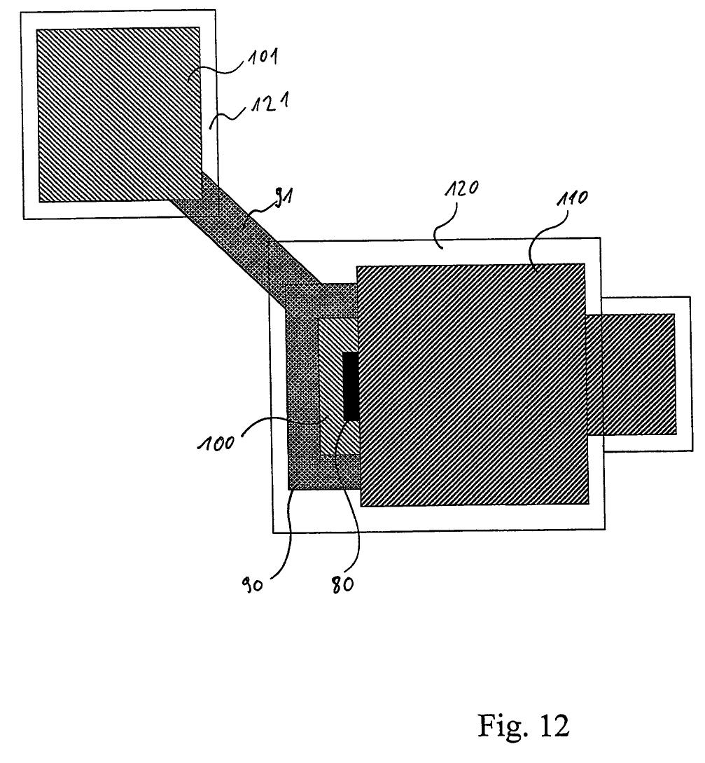

FIG. 12 is a diagrammatic presentation of a mask level for subcollector structuring to insulate the heterobipolar transistor.

FIG. 1 illustrates part of a blank for making a heterobipolar transistor and shows a plurality of layers 12 grown epitaxially on a semi-insulating InP substrate 1. The plurality of layers 12 are grown on the semi-insulating InP substrate 1, for example, by molecular beam epitaxy with lattice adaptation. Doping of the plural layers 12 takes place during the epitaxy. An n⁺ doped InGaAs subcollector layer 2 adjacent to the semi-insulating InP substrate 1 is used for forming a subcollector. Further layers may be positioned between the semi-insulating InP substrate 1 and the n⁺ doped InGaAs subcollector layer 2. In particular, an InP epitaxial layer optionally may be positioned on the semi-insulating substrate 1.

Subsequent adjacent collector layers 13, an n⁺ doped InP layer 3, an InGaAsP layer 4, and a non-intentionally doped InGaAs layer 5 are used to form a collector in the further course of the manufacturing process. The InGaAs layer 5 which is not intentionally doped may be replaced, optionally, by a weakly n⁻ doped layer. A p⁺ doped InGaAs base layer 6 is used for the formation of a base. Directly adjacent to the p⁺ doped InGaAs base layer 6 a non-intentionally doped or weakly doped InGaAs layer 7 is grown. A weakly doped layer has a doping concentration of <10¹⁷·cm⁻³. Together with an n⁻ doped InP layer 8, an n⁺ doped InP layer 9, an n⁺ doped InGaAs layer 10, and an n⁺ doped InGaAs layer 11 the non-intentionally doped or weakly doped InGaAs layer 7 contributes to the formation of an emitter structure.

To begin with, the plural layers 12 deposited epitaxially on the semi-insulating InP substrate 1 are covered by a photoresist film. An emitter mask is transferred to the photoresist film by photolithography. No more than an area 16 of the n⁺ doped InGaAs layer 11 is covered by a remaining emitter photoresist film section 15. The width of the covered area 16 determines an emitter width which may be smaller than 2 μm.

Now, the n⁺ doped InGaAs layer 11 is the first to be structured, either by wet chemical etching or plasma etching. This is followed by etching of the other emitter layers 14 (cf. FIG. 1) constituting an emitter 21. This etching is carried out in consideration of material selection and crystal orientation regarding the n⁺ doped InGaAs layer 11. The etching stops in the zone of the p⁺ doped InGaAs base layer 6 and the non-intentionally or weakly doped InGaAs layer 7. The non-intentionally or weakly doped InGaAs layer 7 may be etched to such an extent as to be completely removed. The non-intentionally or weakly doped InGaAs layer 7 also is referred to as spacer layer. Crystal oriented etching produces etching edges 22, 23 of the emitter layers 14 with an undercut. FIG. 2 illustrates the blank of a heterobipolar transistor upon structuring of the emitter 21. The undercut etching edges 22, 23 may be gathered from this figure.

The formation of an emitter contact 31 and a base contact 32 will be explained with reference to FIG. 3. Once the emitter photoresist film section 15 has been removed from the blank, the blank is covered once again with photoresist material and a base lithography is carried out. When the photoresist film has been developed a base photoresist arrangement 33 remains on the p⁺ doped InGaAs base layer 6. Areas 34, 35 of the p⁺ doped InGaAs base layer 6 which are not to be vapor plated with metal are covered by the base photoresist arrangement 33. During the vaporization process the blank is vapor plated with one or more metal layers by disposing the blank with the base photoresist arrangement 33 upside down vertically above an electron beam vaporizer (not shown). In this manner the emitter contact 31 and the base contact 32 are formed simultaneously in one operating step. Furthermore, a base lead (not shown) and a base connection contact (likewise not shown) may be formed at the same time. A resulting metal layer 36 on the base photoresist arrangement 33 is removed later on together with the base photoresist arrangement 33.

Due to the undercutting of the etching edges 22, 23 the surface of the p⁺ doped InGaAs base layer 6 comprises shaded areas 37, 38 where no metal will be deposited during the vaporization. The shaded areas 37, 38 make sure there will be insulation between the base contact 32 and the emitter 21. When metallizing the p⁺ doped InGaAs base layer 6 and the n⁺ doped InGaAs emitter layer 11, preferably, first a platinum layer is vaporized. Part of the vaporized platinum atoms diffuse into the p⁺ doped InGaAs base layer 6, thus causing a drop in the Schottky barrier level φ_{B}. Thereby the contact resistance is reduced between the p⁺ doped InGaAs base layer 6 and the base contact 32. Preferably a titanium layer, another platinum layer, and a gold layer are vaporized on top of the platinum layer. The base contact 32 and the emitter contact 31 thus obtained are highly resistant to corrosion.

Structuring of the p⁺ doped InGaAs base layer 6 and of part of the collector will be described with reference to FIG. 4. Upon removal of the base photoresist arrangement 33 together with the metal layer 36 the blank in coated once again with a photoresist film. The latter is structured by means of collector lithography such that a collector photoresist arrangement 40 enveloping the emitter 21 is left which completely encloses the emitter 21 and the emitter contact 31. In addition, preferably, only part of the base contact 32 is covered by the collector photoresist arrangement 40. The alignment of the collector lithography mask, used for creating the collector photoresist arrangement 40, with respect to the emitter 21 is not critical because, as explained, the collector photoresist arrangement 40 merely must fully enclose the emitter structure and cover part of the base contact 32. In view of the fact that the base contact 32 is resistant to the etching solutions used, am outer surrounding portion 41 of the base contact 32 defines the structure for etching the p⁺ doped InGaAs base layer 6 and the collector layers 13 underneath it. The p⁺ doped InGaAs base layer 6 and the non-intentionally doped or weakly doped InGaAs layer 6 below it are subjected to wet chemical etching or plasma etching. FIG. 4 illustrates the blank of a heterobipolar transistor upon completion of this etching.

Thereupon the InGaAsP layer 4 and the n⁺ doped InP layer 3 are structured by material selective etching. FIG. 5 shows the blank of a heterobipolar transistor following this etching. Undercut etching edges 51, 52 of a collector 53 may be gathered from this figure.

The etching processes to structure the p⁺ doped InGaAs base layer 6 and the collector 53 additionally provide complete etching under the base lead (not shown). Thus the base lead which connects the base contact 32 with a base connection port (likewise not shown) is devised as an air bridge. Consequently, the base lead has very low capacitance with respect to the collector 53 or the subcollector layer 2.

When the collector photoresist arrangement 40 has been removed the blank of a heterobipolar transistor is coated once more with photoresist and then subcollector lithography is performed. FIG. 6 illustrates a resulting subcollector photoresist arrangement 60.

This step is followed by metallizing of the n⁺ doped InGaAs subcollector layer 2. To accomplish that, the blank is positioned upside down vertically above an electron beam vaporizer (not shown). A collector contact 61 is formed by vaporization. There are shaded areas 62, 63 due to the undercuts of the etching edges 51, 52 of the collector layers 13. During this vaporization step, the collector contact 61 is self-adjusted and formed in insolation from the collector layers 13 of the collector 53. At the same time, the emitter contact 31 and the base contact 32 each receive another layer on top 31′ and 32′, respectively.

The subcollector photoresist arrangement 60 is removed together with the vapor deposited metal layer 64, and the blank is coated again with photoresist. Subsequently an isolation lithography in performed. FIG. 7 shows the resulting isolation photoresist arrangement 70. Subsequently, the subcollector layer 2 is etched to the semi-insulating InP substrate 1 or the InP epitaxy layer which is optionally positioned on the InP substrate 1. This etching preferably is carried out selectively in respect of the material so that it will stop on the semi-insulating InP substrate 1 or the InP epitaxy layer optionally provided on top thereof.

Further steps are carried out in the process upon removal of the isolation photoresist arrangement 70 to passivate and contact the structures of the heterobipolar transistor obtained. An example of how to embody these method steps is disclosed in the applicant's patent application entitled “Integrated Circuit Arrangement” filed at the same date and not described in detail here.

FIGS. 8 to 12 are diagrammatic presentations of mask levels for producing a heterobipolar transistor. Starting with FIG. 9, a respective additional level always is added to the mask levels shown in the preceding figure. The extensions of the structures produced may be taken from the schematic illustrations of the mask levels. FIG. 8 illustrates the dimension of an emitter structure 80. In the embodiment shown, the emitter structure 80 has a width of 2 μm and a length of 5 μm. In addition to the extension of the emitter 80, FIG. 9 shows the extension of a base contact 90, a base lead 91 and a base connection port 92. FIG. 10 additionally shows a mask for collector structuring. It comprises a collector structure mask area 100 which encloses the emitter structure 100. As may be seen, the base contact 90 extends in every direction beyond the maximum dimension of the collector structure mask area 100. Furthermore, it may be seen that the mask for collector structuring completely covers the base connection contact 92 (cf. FIG. 9) by a collector masking area 101. FIG. 11 in addition shows an area 110 in which metal has been vapor deposited on the subcollector. Finally, in FIG. 12 an area 120 is shown which illustrating the size of the subcollector layer 2 once it has been etched. Correspondingly, a region 121 indicates the area under the base connection port 92 that has remained of the subcollector layer 2 on the semi-insulating InP substrate 1 after etching.

The features of the invention disclosed in the specification above, in the drawing and claims may be significant for implementing the invention in its various embodiments, both individually and in any combination.

1. A method of manufacturing a heterobipolar transistor, wherein epitaxially grown layers (12) on a substrate (1) are structured by etching, characterized in that an emitter contact (31) and a base contact (32) are formed by simultaneous metallizing of an emitter layer (11) and a base layer (6).

2. The method as claimed in claim 1, characterized in that when metallizing, platinum is vaporized.

3. The method as claimed in claim 1, characterized in that successive metal layers of platinum, titanium, platinum and gold are vapor deposited when metallizing.

4. The method as claimed in claim 1, characterized in that, prior to metallizing the emitter layer (11) and the base layer (6), an emitter structure (21) is etched in consideration of crystal orientation and material selection so that etching edges (22, 22) of the emitter structure (21) will have an undercut, the etching of the emitter structure (21) being stopped in the zone of a spacer layer (7) or the base layer (6).

5. The method as claimed in claim 4, characterized in that, prior to etching the base layer (6), a photoresist layer is applied around the etched emitter structure (21) so as to fully surround the emitter structure (21) with photoresist material (40) and in such a way that at least part of a surrounding portion (41) of the base contact (32) remote from the emitter structure (21) will not be covered by photoresist material (40).

6. The method as claimed in claim 1, characterised in that a metallic base lead (91) extending between the base contact (32, 90) and a base connection port (92) is completely etched under, whereby an air bridge results.

7. The method as claimed in claim 1, characterized in that a collector structure (53) is formed upon structuring of the base layer (6) and between two successive lithographic steps.

8. The method as claimed in claim 7, characterized in that at least part of the collector structure (53) is etched in consideration of material selection so that etching edges (51, 52) of the collector structure (53) will have an undercut, the etching being stopped on a subcollector material (2).

9. The method as claimed in claim 1, characterized in that the epitaxially grown layers are formed at least partly of III-V semiconductor materials.
